(19) United States
(12) Patent Application Publication
(10) Pub. No.: US 2010/0029072 A1
(43) Pub. Date: Feb. 4, 2010

(54) Methods of Forming Electrical Interconnects Using Thin Electrically Insulating Liners in Contact Holes

(76) Inventors: Jae-Eon Park, Gyeonggi-do (KR); Jun-Keun Kwak, Gyeonggi-do (KR); Jin-Woo Choi, Gyeonggi-do (KR); Sunfei Fang, LaGrangeville, NY (US); Jiang Yan, Newburgh, NY (US)

Correspondence Address: MYERS BIGEL SIBLEY & SAJOVEC, PO BOX 37428, RALEIGH, NC, 27627, US

(21) Appl. No.: 12/507,887

(22) Filed: Jul. 23, 2009

Related U.S. Application Data
(60) Provisional application No. 61/085,170, filed on Jul. 31, 2008.

(51) Int. Cl. H01L 21/768; H01L 21/8234

(52) U.S. Cl. 438/586; 438/643; 438/618; 257/E21.584; 257/E21.585; 257/E21.627

(57) ABSTRACT

Methods of forming integrated circuit devices include forming an electrically insulating layer having a contact hole therein, on a substrate, and then depositing an electrically insulating liner onto a sidewall of the contact hole using an atomic layer deposition (ALD) technique. This electrically insulating liner, which may include gelatinous silica or silicon dioxide, for example, may be deposited to a thickness in a range from 40 Å to 100 Å. A portion of the electrically insulating liner is then removed from a bottom of the contact hole and a barrier metal layer is then formed on the electrically insulating liner and on a bottom of the contact hole. The step of forming the barrier metal layer may be followed by filling the contact hole with a metal interconnect.

### REFERENCE TO PRIORITY APPLICATION

This application claims priority to U.S. Provisional Application Ser. No. 61/085,170, filed Jul. 31, 2008, the disclosure of which is hereby incorporated herein by reference.

### FIELD OF THE INVENTION

The present invention relates to methods of forming integrated circuit devices and, more particularly, to methods of forming integrated circuit devices having metal interconnect structures therein.

### BACKGROUND OF THE INVENTION

Methods of forming highly integrated active devices on semiconductor substrates frequently utilize multiple layers of metallization and electrical interconnects that extend between the multiple layers of metallization. Conventional techniques for forming electrical interconnects frequently include forming an interlayer dielectric layer between a semiconductor substrate and a first layer of metallization and also between each layer of metallization and a next higher layer of metallization. Contact holes/vias are also formed that extend through each of the interlayer dielectric layers. These contact holes may be lined with barrier metal layers and filled with electrical interconnects (e.g., metal interconnects), which may electrically connect one patterned layer of metallization to another patterned layer of metallization. Alternatively, an electrical interconnect may be provided to electrically connect a patterned layer of metallization to an underlying region within the semiconductor substrate. Such interconnects may extend between closely adjacent active devices within the semiconductor substrate. Techniques to form such active devices, which may utilize atomic layer deposition (ALD) techniques, are disclosed in articles by Jae-Eun Park et al., entitled “Mass-Productive Ultra-Low Temperature ALD SiO₂ Process Promising For Sub-90 NM Memory and Logic Devices,” IEDM, pp. 229-232 (2002), and Jong-Ho Yang et al., entitled “Ultimate Solution For Low Thermal Budget Gate Spacer and Etch Stopper to Retard Short Channel Effect in Sub-90 NM Devices,” VLSI Technology Digest of Technical Papers, pp. 55-56 (2003).

### SUMMARY OF THE INVENTION

Methods of forming integrated circuit devices according to embodiments of the present invention include forming an electrically insulating layer having a contact hole therein, on a substrate, and then depositing a very thin electrically insulating liner onto a sidewall of the contact hole using an atomic layer deposition (ALD) technique. This thin liner may operate to prevent formation of electrically conductive “subways” (i.e., electrical shorts) between adjacent contact holes. This electrically insulating liner, which may include gelatinous silica or silicon dioxide, for example, may be deposited to a thickness in a range from about 40 Å to about 100 Å. A portion of the electrically insulating liner is then removed from a bottom of the contact hole and a barrier metal layer is then formed on the electrically insulating liner and on a bottom of the contact hole. The step of forming the barrier metal layer may be followed by filling the contact hole with a metal interconnect. In some of these embodiments of the invention, the barrier metal layer may include titanium and the metal interconnect may include copper.

The step of depositing the electrically insulating liner may include depositing the liner at a temperature in a range from about 75° C. to about 150° C. In addition, the step of removing a portion of the electrically insulating liner may be preceded by a step of densifying the electrically insulating liner in a vacuum having a pressure in a range from about 0.5 torr to about 1.5 torr. This densifying may also include annealing the electrically insulating liner at a temperature of greater than 250° C., and even possibly in a range from about 400° C. to about 500° C., for a duration in a range from about 30 seconds to about two minutes. The step of removing the portion of the electrically insulating liner may include anisotropically etching the portion of the electrically insulating liner from the bottom of the contact hole.

Methods of forming integrated circuit devices according to additional embodiments of the invention include forming a plurality of gate electrodes on a semiconductor substrate and forming an electrically insulating layer on the plurality of gate electrodes. A contact hole is then formed that extends through the electrically insulating layer. This contact hole exposes a portion of the semiconductor substrate extending adjacent at least one of the plurality of gate electrodes. An electrically insulating liner is then deposited onto a sidewall of the contact hole using an atomic layer deposition (ALD) technique. This electrically insulating liner is then densified by annealing the electrically insulating liner at a temperature in a range from about 250° C. to about 500° C. A portion of the electrically insulating liner at a bottom of the contact hole is then anisotropically etched for a sufficient duration to expose the semiconductor substrate. A barrier metal layer is then formed on the electrically insulating liner, within the contact hole. The contact hole is then filled with a metal interconnect. The step of depositing the electrically insulating liner onto a sidewall of the contact hole may include depositing a gelatinous silica layer onto the sidewall of the contact hole, by reacting a silicon halide with water at a temperature in a range from about 75° C. to about 150° C. This silicon halide may be Si₂Cl₆.

Still further embodiments of the invention include methods of forming an integrated circuit device by forming an electrically insulating layer having a contact hole therein, on a substrate, and then depositing a gelatinous silica layer onto the sidewall of the contact hole by reacting silicon halide with water at a temperature in a range from about 75° C. to about 150° C. The gelatinous silica layer is then densified by annealing the gelatinous silica layer at a temperature in a range from about 250° C. to about 500° C. A portion of the densified gelatinous silica layer is removed from a bottom of the contact hole before the contact hole is filled with an electrical interconnect (e.g., copper interconnect). The silicon halide may be Si₂Cl₆ and the step of densifying the gelatinous silica layer may include densifying the gelatinous silica layer in a vacuum having a pressure in a range from about 0.5 torr to about 1.5 torr.

### BRIEF DESCRIPTION OF THE DRAWINGS

FIG. 1 is a flow diagram of steps that illustrates methods of forming integrated circuit devices according to embodiments of the present invention.

FIG. 2 is a flow diagram of steps that illustrates methods of forming integrated circuit devices according to embodiments of the present invention.

FIG. 3 is a flow diagram of steps that illustrates methods of forming integrated circuit devices according to embodiments of the present invention.

FIGS. 4A-4C are cross-sectional views of intermediate structures that illustrate methods of forming integrated circuit devices according to embodiments of the present invention.

### DETAILED DESCRIPTION OF PREFERRED EMBODIMENTS

The present invention now will be described more fully herein with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the scope of the invention to those skilled in the art. Like reference numerals refer to like elements throughout.

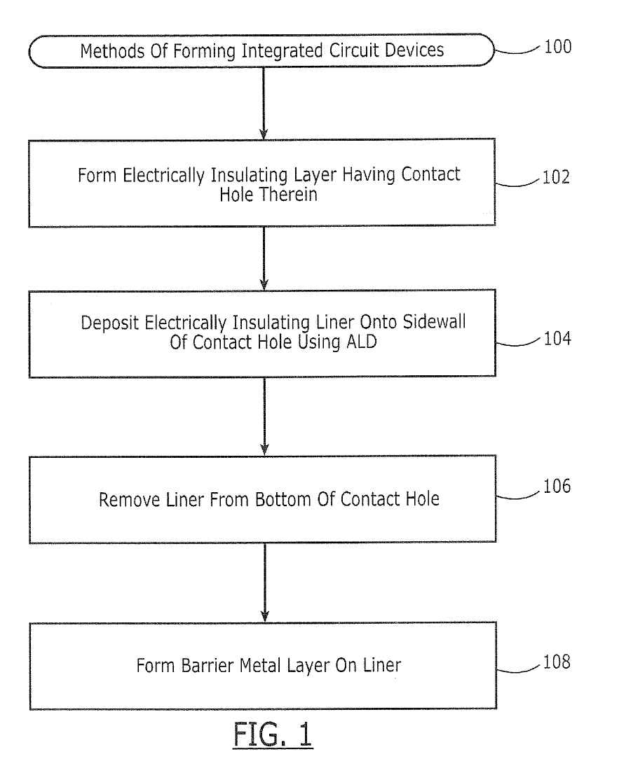

Referring now to the flow diagram of FIG. 1, methods of forming integrated circuit devices 100 according to first embodiments of the present invention include forming an electrically insulating layer having a contact hole therein, on a substrate, Block 102, and then depositing an electrically insulating liner onto a sidewall of the contact hole using an atomic layer deposition (ALD) technique, Block 104. A portion of the electrically insulating liner is then selectively removed from a bottom of the contact hole, Block 106, prior to forming a barrier metal layer on the electrically insulating liner, Block 108. This step of forming the barrier metal layer may be followed by a step of filling the contact hole with a metal interconnect. In some of these embodiments of the invention, the barrier metal layer may include titanium and the metal interconnect may include copper.

The electrically insulating liner, which may include gelatinous silica or silicon dioxide, for example, may be deposited to a thickness in a range from about 40 Å to about 100 Å, at a temperature in a range from about 75° C. to about 150° C. In addition, the step of removing a portion of the electrically insulating liner, Block 106, may be preceded by a step of densifying the electrically insulating liner in a vacuum having a pressure in a range from about 0.5 torr to about 1.5 torr. This densifying may also include annealing the electrically insulating liner at a temperature of greater than 250° C., and even possibly in a range from about 400° C. to 500° C., for a duration in a range from about 30 seconds to about two minutes. The step of removing the portion of the electrically insulating liner, Block 106, may include anisotropically etching the portion of the electrically insulating liner from the bottom of the contact hole.

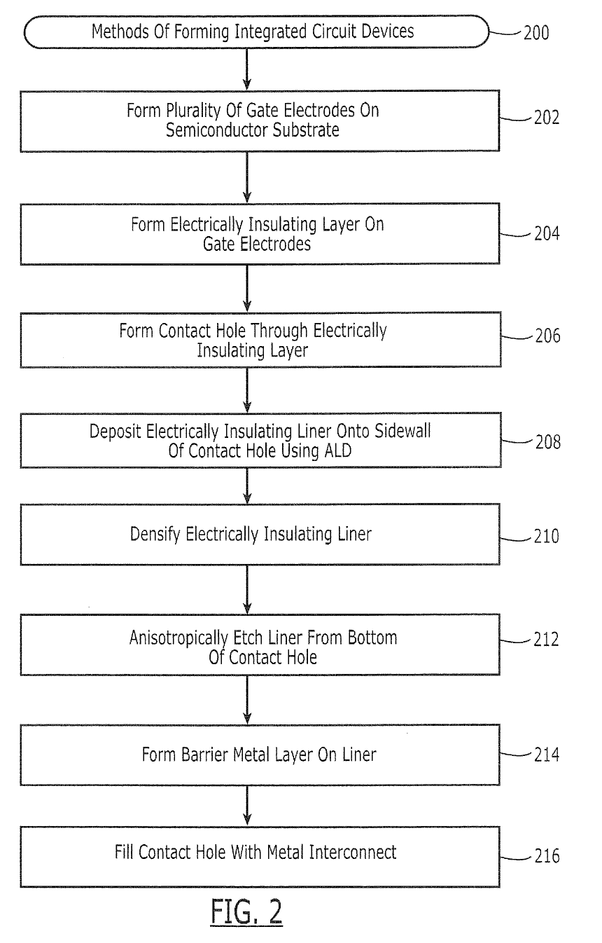

Referring now to the flow diagram of FIG. 2, methods of forming integrated circuit devices 200 according to second embodiments of the present invention include forming a plurality of gate electrodes on a semiconductor substrate, Block 202, and then forming an electrically insulating layer on the plurality of gate electrodes, Block 204. A contact hole is then formed, which extends through the electrically insulating layer, Block 206. This contact hole is formed to expose a portion of the semiconductor substrate extending adjacent at least one of the plurality of gate electrodes. A thin electrically insulating liner is then deposited onto a sidewall of the contact hole using an atomic layer deposition (ALD) technique, Block 208. In particular, the thin electrically insulating liner is formed by depositing a gelatinous silica layer onto the sidewall of the contact hole. This deposition step may be performed by reacting a silicon halide with water at a temperature in a range from about 75° C. to about 150° C. The silicon halide may be Si₂Cl₆.

The electrically insulating liner is then densified by annealing the electrically insulating liner at a temperature in a range from about 250° C. to about 500° C., Block 210. A portion of the electrically insulating liner at a bottom of the contact hole is then selectively etched for a sufficient duration to expose the semiconductor substrate, Block 212, prior to forming a barrier metal layer on the electrically insulating liner, Block 214. The contact hole is then filled with a metal interconnect (e.g., copper interconnect), Block 216.

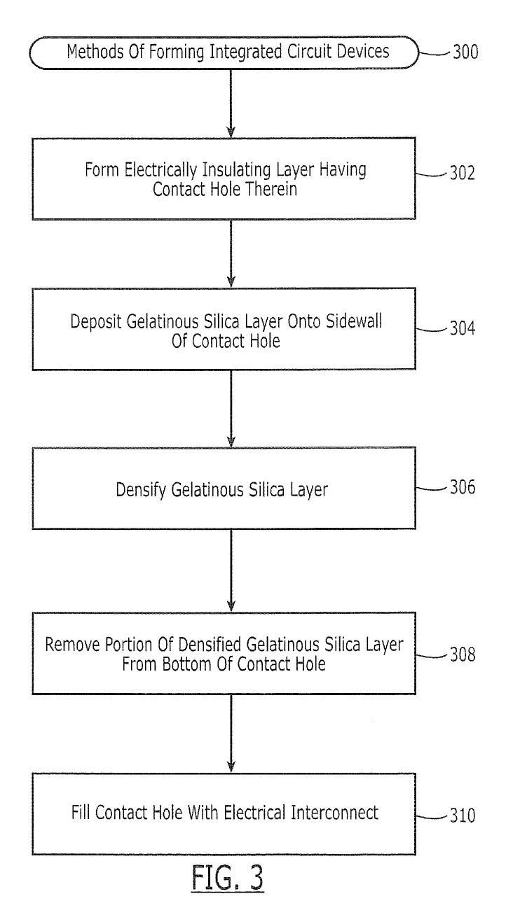

According to the flow diagram of FIG. 3, methods of forming integrated circuit devices 300 according to third embodiments of the present invention include forming an electrically insulating layer having a contact hole therein, on a substrate, Block 302, and then depositing a gelatinous silica layer onto the sidewall of the contact hole by reacting a silicon halide (e.g., Si₂Cl₆) with water at a temperature in a range from about 75° C. to about 150° C., Block 304. The gelatinous silica layer is then densified by annealing the gelatinous silica layer at a temperature in a range from about 250° C. to about 500° C., Block 306. This densification step may be performed in a vacuum having a pressure in a range from about 0.5 torr to about 1.5 torr. This densification step is performed prior to removing a portion of the densified gelatinous silica layer from a bottom of the contact hole, Block 308. The contact hole is then filled with an electrical interconnect, Block 310.

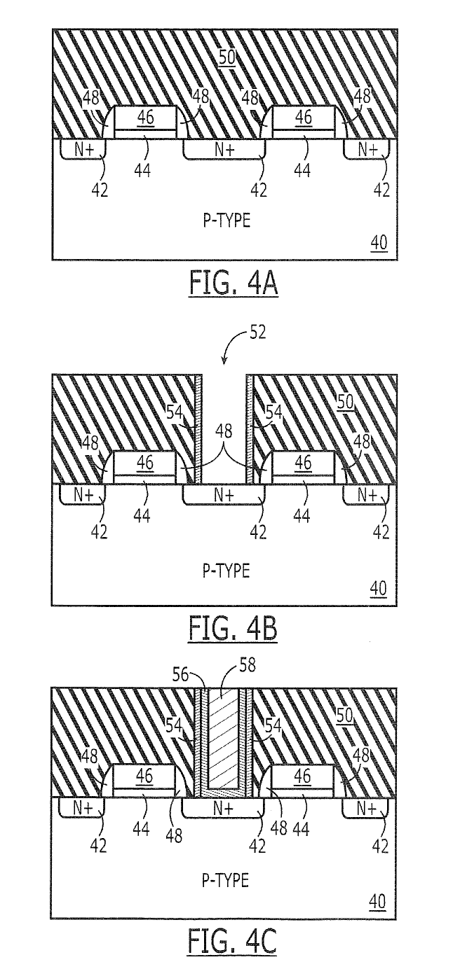

These methods of FIGS. 1-3 are further illustrated by FIGS. 4A-4C, which are cross-sectional views of intermediate structures that illustrate methods of forming integrated circuit devices according to embodiments of the present invention. As illustrated by FIG. 4A, a plurality of gate electrodes 46 are formed on a surface of a semiconductor substrate having a P-type semiconductor region 40 therein. These gate electrodes 46 are separated from the substrate by corresponding gate insulating layers 44 and the sidewalls of the gate electrodes 46 are protected by sidewall insulating spacers 48. The P-type semiconductor region 40 also includes source/drain regions 42 (shown as N+ regions). As illustrated by Block 204 in FIG. 2 and FIG. 4A, an electrically insulating layer 50 is formed on the gate electrodes 46.

Referring now to FIG. 4B and Block 206 of FIG. 2, a contact hole 52 is formed in the electrically insulating layer 50. This contact hole 52 is illustrated as extending through the electrically insulating layer 50 and exposing a source/drain region 42. Then, as shown by Block 208, an electrically insulating liner 54 (e.g., gelatinous silica) is deposited onto a sidewall of the contact hole 52, using an atomic layer deposition (ALD) technique. This liner 54 is densified and then anisotropically etched to expose the underlying source/drain region 42 at a bottom of the contact hole 52, Blocks 210, 212. Thereafter, as illustrated by FIG. 4C and Blocks 214 and 216 in FIG. 2, a barrier metal layer 56 is formed on the liner 54 and then the contact hole 52 is filled with a metal interconnect 58. According to some of these embodiments of the invention, the barrier metal layer 56 may include titanium and the metal interconnect 58 may include copper.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. A method of forming an integrated circuit device, comprising:
forming an electrically insulating layer having a contact hole therein, on a substrate;
depositing an electrically insulating liner onto a sidewall of the contact hole using an atomic layer deposition (ALD) technique;
removing a portion of the electrically insulating liner from a bottom of the contact hole; and then
forming a barrier metal layer on the electrically insulating liner.

2. The method of claim 1, wherein said depositing step comprises depositing the electrically insulating liner at a temperature in a range from about 75° C. to about 150° C.

3. The method of claim 1, wherein said removing step is preceded by a step of densifying the electrically insulating liner in a vacuum having a pressure in a range from about 0.5 torr to about 1.5 torr.

4. The method of claim 3, wherein densifying the electrically insulating liner comprises annealing the electrically insulating liner at a temperature in a range from about 250° C. to about 500° C.

5. The method of claim 1, wherein said removing step comprises anisotropically etching the portion of the electrically insulating liner from the bottom of the contact hole.

6. The method of claim 1, wherein said removing step is preceded by a step of annealing the electrically insulating liner at a temperature in a range from about 250° C. to about 500° C.

7. The method of claim 6, wherein the deposited electrically insulating liner comprises gelatinous silica.

8. The method of claim 1, wherein depositing an electrically insulating liner comprises depositing an electrically insulating liner having a thickness in a range from about 40 Å to about 100 Å onto the sidewall of the contact hole.

9. The method of claim 8, wherein the electrically insulating liner comprises silicon dioxide.

10. The method of claim 1, wherein forming a barrier metal layer is followed by filling the contact hole with a metal interconnect.

11. The method of claim 10, wherein the barrier metal layer comprises titanium; and wherein the metal interconnect comprises copper.

12. The method of claim 4, wherein densifying the electrically insulating liner comprises annealing the electrically insulating liner at a temperature in a range from about 400° C. to about 500° C.

13. The method of claim 4, wherein densifying the electrically insulating liner comprises annealing the electrically insulating liner at a temperature in a range from about 400° C. to about 500° C., for a duration in a range between 30 seconds and two minutes.

14. A method of forming an integrated circuit device, comprising:
forming a plurality of gate electrodes on a semiconductor substrate;
forming an electrically insulating layer on the plurality of gate electrodes;
forming a contact hole that extends through the electrically insulating layer and exposes a portion of the semiconductor substrate extending adjacent at least one of the plurality of gate electrodes;
depositing an electrically insulating liner onto a sidewall of the contact hole using an atomic layer deposition (ALD) technique;
densifying the electrically insulating liner by annealing the electrically insulating liner at a temperature in a range from about 250° C. to about 500° C.;
anisotropically etching a portion of the electrically insulating liner at a bottom of the contact hole for a sufficient duration to expose the semiconductor substrate; then
forming a barrier metal layer on the electrically insulating liner; and then
filling the contact hole with a metal interconnect.

15. The method of claim 14, wherein depositing an electrically insulating liner onto a sidewall of the contact hole comprises depositing a gelatinous silica layer onto the sidewall of the contact hole.

16. The method of claim 15, wherein depositing a gelatinous silica layer onto the sidewall of the contact hole comprises reacting a silicon halide with water at a temperature in a range from 75° C. to 150° C.

17. The method of claim 16, wherein the silicon halide is Si₂Cl₆.

18. A method of forming an integrated circuit device, comprising:
forming an electrically insulating layer having a contact hole therein, on a substrate;
depositing a gelatinous silica layer onto the sidewall of the contact hole by reacting a silicon halide with water at a temperature in a range from 75° C. to 150° C.;
densifying the gelatinous silica layer by annealing the gelatinous silica layer at a temperature in a range from about 250° C. to about 500° C.;
removing a portion of the densified gelatinous silica layer from a bottom of the contact hole; and then
filling the contact hole with an electrical interconnect.

19. The method of claim 18, wherein the silicon halide is Si₂Cl₆.

20. The method of claim 18, wherein densifying the gelatinous silica layer comprises densifying the gelatinous silica layer in a vacuum having a pressure in a range from about 0.5 torr to about 1.5 torr.
